(19) United States
(12) Patent Application Publication
(10) Pub. No.: US 2025/0165681 A1
(43) Pub. Date: May 22, 2025

(54) NDVI AND NDRE MODELS TO DETERMINE TILLER DENSITY IN WINTER WHEAT

(71) Applicant: VIRGINIA TECH INTELLECTUAL PROPERTIES, INC., Blacksburg, VA (US)

(72) Inventors: Joseph Oakes, Tappahannock, VA (US); Maria Balota, Suffolk, VA (US); Wade Thomason, Stillwater, OK (US); Alexandre-Brice Cazenave, Blacksburg, VA (US)

(21) Appl. No.: 18/955,434

(22) Filed: Nov. 21, 2024

Related U.S. Application Data
(60) Provisional application No. 63/601,588, filed on Nov. 21, 2023.

(51) Int. Cl. G06F 30/27; A01G 22/22

(52) U.S. Cl. CPC G06F 30/27; A01G 22/22

(57) ABSTRACT

Various embodiments for determining fertilizer application for crops based on aerial-based vegetation indices are described. In one example, a method includes determining a relationship between an aerial vegetation index for a crop and tiller density of the crop. The method further includes creating a fertilizer application model for the crop based at least in part on recommended fertilizer application data for the crop and the relationship between the aerial vegetation index and the tiller density of the crop. The recommended fertilizer application data being correlated with the tiller density of the crop.

### CROSS REFERENCE TO RELATED APPLICATIONS

This application claims the benefit of and priority to U.S. Provisional Application Ser. No. 63/601,588, filed Nov. 21, 2023, and titled “NDVI AND NDRE MODELS TO DETERMINE TILLER DENSITY IN WINTER WHEAT,” the entire contents of which are hereby incorporated herein by reference.

### BACKGROUND

Planting date, seeding rate, nutrient availability, and application timing can have an effect on the success of tiller development. It is essential for growers to plan ahead by using soil sampling techniques to help determine if a pre-plant fertilizer application is needed and to implement tiller counts or the use of indices such as the normalized difference vegetation index (NDVI) at the correct growth stages for a more precise nutrient recommendation and timely application of nitrogen. Ideal planting conditions based on forecasted weather events can encourage fall tiller production, but many environmental factors are variable and can affect the yield of a winter wheat crop. By using management techniques that can be controlled, yield potential can be optimized with the promotion of tiller initiation and establishment.

### BRIEF DESCRIPTION OF THE DRAWINGS

Many aspects of the present disclosure can be better understood with reference to the following figures. The components in the figures are not necessarily to scale, with emphasis instead being placed upon clearly illustrating the concepts of the disclosure. Moreover, repeated use of reference characters or numerals in the figures is intended to represent the same or analogous features, elements, or operations across different figures. Repeated description of such repeated reference characters or numerals is omitted for brevity.

FIG. 1 illustrates a block diagram of an example environment according to various aspects and embodiments of the present disclosure.

FIG. 2 illustrates another block diagram of the environment shown in FIG. 1 according to various aspects and embodiments of the present disclosure.

FIG. 3 illustrates an example fertilizer application model according to various aspects and embodiments of the present disclosure.

FIG. 4 illustrates a flow diagram of an example computer-implemented method according to various aspects and embodiments of the present disclosure.

### DETAILED DESCRIPTION

Tiller production in crops, including cereal crops such as winter wheat (Triticum aestivum L.), is the development of shoots from buds at the base of the main stem and is a critical factor to final yield. Early leaf and tiller development is crucial because the number of tillers per plant is a critical yield component. This is because tillers initiated in the fall make up the majority of spikes, compared to tillers initiated from January 1^{st} to Zadok's growth stage (GS) 30, and contribute up to 87% of grain yield. That is, while tillers will continue to develop into the spring, the tillers produced in the fall will contribute the most toward yield. One study showed that when tiller density is low in spring, nitrogen (N) should be split and applied at GS 25 and GS 30 to stimulate additional yield.

If tiller densities are not sufficient in late January to early February, N should be applied to optimize and stimulate the needed tiller growth. Any tiller produced in March or later contributes less than 2% to the overall yield. The number of tillers per square meter (or “tiller density”) is the proper metric and method for determining whether a crop needs a split N application at GS 25. If a crop has a tiller density of 538 tillers per square meter (tillers/m²) or greater, a single N application at GS 30 is sufficient. If the tiller density is less than 538 tillers/m², N should be applied at GS 25. If the tiller density is 323 to 537 tillers/m², approximately 45 to 56 kilograms N per hectare (kg N ha⁻¹) should be applied. If tiller density is relatively thin with 215 to 322 tillers/m², approximately 56 to 78 kg N ha⁻¹ should be applied.

Worldwide, 18% of N applied to cropping systems is applied to wheat and this is one of the largest expenses to producers, with the cost continuing to rise. From 2021 to 2022, the price of one of the most common liquid N fertilizers increased by 267%. However, wheat typically only uses approximately 33% of N application, with the rest being lost through leaching, volatilization, and denitrification, or immobilization which is not a loss. Leaching of N can pollute ground and surface waters, causing acidification, eutrophication of aquatic systems, and toxicity to animals. Therefore, a method to apply N based on need rather than a blanket application would be beneficial.

Even though applying N based on tiller density has been proven beneficial to wheat production, it is often not utilized due to tiller variability across the field and the amount of time involved in physically counting tillers. Vegetation indices incorporating red and near-infrared (NIR) canopy reflectance, such as the normalized difference vegetation index (NDVI) and the normalized difference red edge (NDRE) index, are now widely used for N monitoring models for several crops. Previous work on 22 site-years in Virginia from 2000 to 2002 has shown that ground collected NDVI was well correlated with tiller density, with a coefficient of determination or r-squared (r²) value of 0.74, indicating that NDVI collected with hand-held optical sensors at GS 25 has the ability to predict tiller density without having to physically count the tillers. While the study found that there is a saturation point at which NDVI will no longer increase as tiller density increases, this occurs beyond GS 25 when an N recommendation would be needed.

Aerial indices from UAV platforms or satellite can often outperform ground measurements as they provide an overall view of the entire area, not just a small area where the hand-held reflectance sensor is being pointed. For example, ground indices for a peanut crop in one study predicted leaf loss from disease at an r² of 0.30, while aerial indices for the crop predicted leaf loss at an r² of 0.73. Another study also found that aerial NDVI was correlated with ground NDVI at an r² of 0.89. Similarly, another study found that image data from an UAV could non-destructively diagnose wheat N status, and still another study found that an active sensor mounted to an UAV platform could successfully monitor the growth and N nutrition status of winter wheat.

While work has been carried out using ground NDVI and aerial sensors towards monitoring crop N status, little work has specifically examined the relationship between aerial indices and early season tiller density to determine N split application rates in winter wheat production. As a solution, embodiments herein can determine a relationship between aerial-based vegetation indices and tiller densities for a cereal crop (e.g., winter wheat) and create a fertilizer application model for N application requirements at GS 25 based at least in part on such a correlation between the crop's aerial-based vegetation indices and tiller densities.

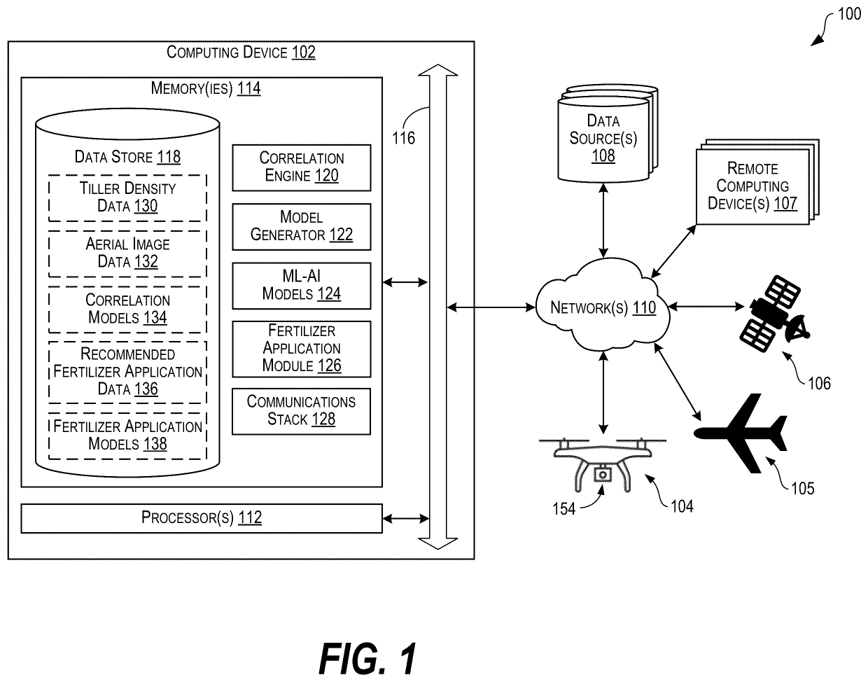

For context, FIG. 1 illustrates a block diagram of an example environment 100 according to various aspects and embodiments of the present disclosure. The environment 100 can be a computing environment in which various types of computing operations can be performed, among other operations. The environment 100 is illustrated as a representative example, and the fertilizer application framework concepts described herein are not limited to use with any particular type of computing environment.

The environment 100 includes a computing device 102 and one or more aeronautical or astronomical vehicles such as an unmanned aerial vehicle (UAV) 104, an airplane 105, and a satellite 106 in this example. The environment 100 further includes one or more remote computing devices 107, one or more data sources 108, and one or more networks 110 in the example shown, among other components. The computing device 102, the UAV 104, the airplane 105, the satellite 106, the remote computing devices 107, and the data sources 108 are coupled to one another in this example by way of the networks 110.

Any or all of the UAV 104, the airplane 105, or the satellite 106 can include one or more sensors such as a multispectral imaging sensor or camera that can be configured to capture aerial-based spectrometric image data indicative of a cereal crop. The UAV 104 includes a multispectral imaging camera 154 in the example shown, and each of the airplane 105 and the satellite 106 include the same or similar multispectral imaging device having the same or similar capabilities as that of the multispectral imaging camera 154. Examples of aerial-based spectrometric image data of a cereal crop that can be captured by the multispectral imaging camera 154 include, but are not limited to, visual spectrum and multispectral image data, spectral or spectrometric image data, spectral reflectance measurements data obtained from near-infrared (NIR), red (R), and edge of red or red edge (RE) wavelength ranges, other aerial-based spectrometric image data of the crop, or any combination thereof. Any or all of the UAV 104, the airplane 105, the satellite 106, or the data sources 108 can also include one or more computing devices or systems (e.g., memory, processor, microprocessor, controller) and communication systems (e.g., transmitter, receiver, transceiver, modulator) that can be configured to collectively process, store, and communicate such aerial-based spectrometric image data (e.g., via the networks 110) and other data described herein.

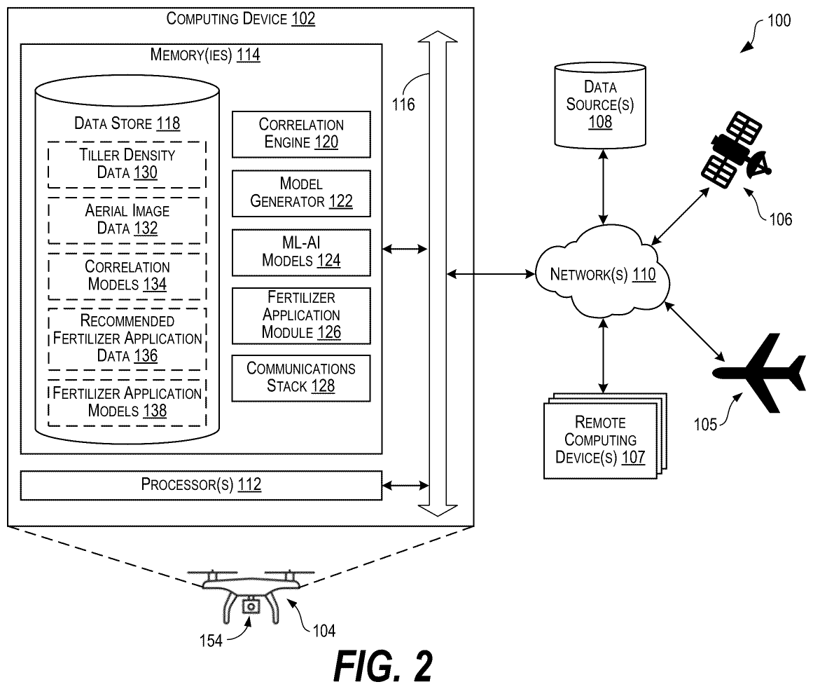

The computing device 102 and any or all of the remote computing devices 107 can each be embodied or implemented as one or more of a server computing device, a client computing device, a general-purpose computer, a special-purpose computer, a virtual machine, a supercomputer, a laptop, a tablet, a smartphone, a wearable device, or another type of computing device that can be configured and operable to perform various operations described herein. A detailed description of the computing device 102 and the operations it can perform is provided in examples herein. In some cases, the computing device 102 or similar device can be included in or coupled to one or more of the UAV 104, the airplane 105, the satellite 106, or the data sources 108. For instance, the computing device 102 can be included in or coupled to the UAV 104 as shown in FIG. 2. FIG. 2 illustrates another block diagram of the environment 100 according to various aspects and embodiments of the present disclosure. In the environment 100 illustrated in FIG. 2, the computing device 102 is included in the UAV 104, and it can perform all the same functions described herein with reference to the environment 100 illustrated in FIG. 1.

Referring among FIGS. 1 and 2, the data sources 108 can each be embodied as a digital data source that can be accessed by the computing device 102 such as an online website, repository, database, another type of digital data source, or any combination thereof. The data sources 108 can include a plurality of digital resources having data and information that are indicative of or describe various agricultural related topics such as recommended fertilizer application timing and rates for different tiller densities of different cereal crops, among other agricultural related topics. The data sources 108 can be embodied in many examples as a collection of digital publications, articles, books, journals, illustrations, videos, other digital forms of such data and information. The data sources 108 in many cases can include recommended fertilizer application timing and rates for different tiller densities of winter wheat.

The networks 110 can include, for instance, the Internet, intranets, extranets, wide area networks (WANs), local area networks (LANs), wired networks, wireless networks (e.g., cellular, WiFi®), cable networks, satellite networks, other suitable networks, or any combinations thereof. The computing device 102, the UAV 104, the airplane 105, the satellite 106, the remote computing devices 107, and the data sources 108 can communicate data with one another over the networks 110 using any suitable systems interconnect models and/or protocols. Example interconnect models and protocols include hypertext transfer protocol (HTTP), simple object access protocol (SOAP), representational state transfer (REST), real-time transport protocol (RTP), real-time streaming protocol (RTSP), real-time messaging protocol (RTMP), user datagram protocol (UDP), internet protocol (IP), transmission control protocol (TCP), and/or other protocols for communicating data over the networks 110, without limitation. Although not illustrated, the networks 110 can also include connections to any number of other network hosts, such as website servers, file servers, networked computing resources, databases, data stores, or other network or computing architectures in some cases.

Among other operations, the computing device 102 can be configured to determine a fertilizer application time and rate for a cereal crop, as one example crop, using an aerial-based vegetation index and recommended fertilizer application data corresponding to the cereal crop. For instance, the computing device 102 can be configured to determine a fertilizer application time and rate for a cereal crop using an aerial-based vegetation index such as an aerial-based NDVI or NDRE to predict a tiller density of the crop. The computing device 102 can be further configured to then use recommended fertilizer application data to determine a recommended fertilizer application time (e.g., GS 25, GS 30) and rate (e.g., mass of fertilizer per area) corresponding to the tiller density predicted for the cereal crop.

To predict the tiller density of a cereal crop using an aerial-based vegetation index, the computing device 102 can be configured in some examples to determine a relationship between the aerial-based vegetation index and the tiller density as described further herein. The computing device 102 can also be configured in some examples to create a fertilizer application model for the cereal crop using recommended fertilizer application data for the cereal crop and the relationship between the aerial-based vegetation index and the tiller density of the crop. The recommended fertilizer application data for the cereal crop can be indicative of and include different recommended fertilizer application times and rates corresponding to different tiller densities or ranges of tiller densities for the crop. Once created, the computing device 102 and other entities can use the fertilizer application model in many cases to determine different fertilizer application times and rates for the cereal crop based on different aerial-based vegetation indices corresponding to the crop.

To determine a fertilizer application time and rate for a cereal crop using an aerial-based vegetation index and recommended fertilizer application data corresponding to the cereal crop in various examples, the computing device 102 can include at least one processing and memory system. The computing device 102 in this example includes at least one processor 112 and at least one memory 114, both of which are communicatively coupled, operatively coupled, or both, to a local interface 116. The memory 114 includes a data store 118, a correlation engine 120, a model generator 122, machine learning and artificial intelligence (ML-AI) models 124 (also “ML-AI models 124”), a fertilizer application module 126, and a communications stack 128 in the example shown. The computing device 102 is coupled to the networks 110 by way of the local interface 116 in this example. The computing device 102 can also include other components that are not illustrated in FIG. 1. The data store 118 in this example includes tiller density data 130, aerial image data 132, one or more correlation models 134, recommended fertilizer application data 136, and one or more fertilizer application models 138.

The processor 112 can be embodied as or include any processing device (e.g., a processor core, a microprocessor, an application specific integrated circuit (ASIC), a field-programmable gate array (FPGA), a controller, a microcontroller, or a quantum processor) and can include one or multiple processors that can be operatively connected. In some examples, the processor 112 can include one or more complex instruction set computing (CISC) microprocessors, one or more reduced instruction set computing (RISC) microprocessors, one or more very long instruction word (VLIW) microprocessors, or one or more processors that are configured to implement other instruction sets.

The memory 114 can be embodied as one or more memory devices and can store data and software or executable-code components executable by the processor 112. For example, the memory 114 can store executable-code components associated with the correlation engine 120, the model generator 122, the ML-AI models 124, the fertilizer application module 126, and the communications stack 128 for execution by the processor 112. The memory 114 can also store data such as the data described below that can be stored in the data store 118, among other data. For instance, the memory 114 can also store data indicative of at least one of the tiller density data 130, the aerial image data 132, the correlation models 134, the recommended fertilizer application data 136, or the fertilizer application models 138.

The memory 114 can store other executable-code components for execution by the processor 112. For example, an operating system can be stored in the memory 114 for execution by the processor 112. Where any component discussed herein is implemented in the form of software, any one of a number of programming languages can be employed such as, for example, C, C++, C#, Objective C, JAVA®, JAVASCRIPT®, Perl, PHP, VISUAL BASIC®, PYTHON®, RUBY, FLASH®, or other programming languages.

As discussed above, the memory 114 can store software for execution by the processor 112. In this respect, the terms “executable” or “for execution” refer to software forms that can ultimately be run or executed by the processor 112, whether in source, object, machine, or other form. Examples of executable programs include, for instance, a compiled program that can be translated into a machine code format and loaded into a random access portion of the memory 114 and executed by the processor 112, source code that can be expressed in an object code format and loaded into a random access portion of the memory 114 and executed by the processor 112, source code that can be interpreted by another executable program to generate instructions in a random access portion of the memory 114 and executed by the processor 112, or other executable programs or code.

The local interface 116 can be embodied as a data bus with an accompanying address/control bus or other addressing, control, and/or command lines. In part, the local interface 116 can be embodied as, for instance, an on-board diagnostics (OBD) bus, a controller area network (CAN) bus, a local interconnect network (LIN) bus, a media oriented systems transport (MOST) bus, ethernet, or another network interface.

The data store 118 can include data for the computing device 102 such as, for instance, one or more unique identifiers for the computing device 102, digital certificates, encryption keys, session keys and session parameters for communications, and other data for reference and processing. Among other data, the data store 118 in the example shown includes the tiller density data 130, the aerial image data 132, the correlation models 134, the recommended fertilizer application data 136, and the fertilizer application models 138. The data store 118 can also store computer-readable instructions for execution by the computing device 102 via the processor 112, including instructions for the correlation engine 120, the model generator 122, the ML-AI models 124, the fertilizer application module 126, and the communications stack 128 in many cases.

The tiller density data 130 can include and be indicative of different ground-truth tiller densities for one or more crops such as cereal crops. Example cereal crops can include, but are not limited to, wheat, winter wheat, rice, corn, barley, oats, rye, millet, sorghum, or another cereal crop. The ground-truth tiller densities can be determined in many cases at different growth stages (e.g., GS 25, GS 30) for crops at the same or different locations, crops planted according to the same or different planting method, crops exposed to the same or different environmental conditions, crops having the same or different planting or plot arrangements or orientations, crops having the same or different water application times or rates, crops fertilized according to the same or different fertilizer application times or rates, or any combination thereof. The ground-truth tiller densities can be determined in some cases by counting the number of tillers located within each square meter (m²) of a planted crop. The tiller density data 130 can be used by the computing device 102 in many examples to determine a relationship between a cereal crop's aerial-based vegetation index and its tiller density. For instance, the tiller density data 130 can be used by the computing device 102 in many examples to create the correlation models 134 as described further herein.

The aerial image data 132 can include and be indicative of aerial-based spectrometric image data corresponding to and indicative of one or more crops such as cereal crops. Example aerial-based spectrometric image data of a cereal crop can include, but is not limited to, visual spectrum and multispectral image data, spectral or spectrometric image data, spectral reflectance measurements data obtained from NIR, R, and RE wavelength ranges, other aerial-based spectrometric image data of the crop, or any combination thereof. The aerial-based spectrometric image data can be captured using a multispectral imaging sensor or camera coupled to at least one of an aeronautical or astronomical vehicle. For instance, the aerial-based spectrometric image data can be captured using the multispectral imaging camera 154 or another multispectral camera and the UAV 104, the airplane 105, the satellite 106, or another aerial or orbital vehicle. The aerial-based spectrometric image data of a cereal crop can be captured at approximately the same time (e.g., same day, same hour) as the tiller density data 130 for the crop is determined in many cases. The aerial image data 132 can be used by the computing device 102 in many examples to calculate an aerial-based vegetation index for a cereal crop and determine a relationship between the crop's aerial-based vegetation index and its tiller density. For instance, the tiller density data 130 can be used by the computing device 102 in many examples to create the correlation models 134 as described further herein.

The correlation models 134 can be embodied and implemented as or include one or more functions, equations, algorithms, other models, or any combination thereof that define a relationship between a cereal crop's aerial-based vegetation index and its tiller density in many examples. For instance, each of the correlation models 134 can be embodied and implemented as a function or equation that defines a relationship between different aerial-based vegetation indices and tiller densities of a certain cereal crop. The computing device 102 can be configured to create the correlation models 134 for various cereal crops using respective aerial image data 132 and tiller density data 130 corresponding to such crops in many cases.

For instance, the computing device 102 can be configured to use respective aerial image data 132 and tiller density data 130 corresponding to a certain cereal crop to determine a correlation coefficient indicative of magnitude and direction of a linear correlation between aerial-based vegetation indices and tiller densities of such a crop. The computing device 102 can also be configured in many examples to use respective aerial image data 132 and tiller density data 130 corresponding to a certain cereal crop to perform a linear regression method to fit a linear correlation between aerial-based vegetation indices and tiller densities of such a crop.

A correlation function or equation indicative of such a linear relationship between the aerial-based vegetation indices and tiller densities of the crop can then be defined by the computing device 102 based at least in part on performing the linear regression method in many cases. Such a correlation function or equation derived by way of linear regression (e.g., using a linear regression algorithm and method) can be an embodiment of one of the correlation models 134 in these examples.

The recommended fertilizer application data 136 can include and be indicative of recommended fertilizer application timing and rates for different tiller densities of different cereal crops in many examples. For instance, the recommended fertilizer application data 136 can include and be indicative of a recommended fertilizer application for winter wheat that suggests a single N application at GS 30 is sufficient for a tiller density of 538 tillers/m² or greater. Such a recommended fertilizer application for winter wheat can further suggest a fertilizer application of approximately 45 to 56 kg N ha⁻¹ should be applied at GS 25 if the tiller density is 323 to 537 tillers/m².

The recommended fertilizer application can also suggest a fertilizer application of approximately 56 to 78 kg N ha⁻¹ should be applied at GS 25 if the tiller density is 215 to 322 tillers/m². The computing device 102 can be configured to obtain the recommended fertilizer application data 136 from the data sources 108 by way of the networks 110 in most cases. The recommended fertilizer application data 136 and one of the correlation models 134 can be used by the computing device 102 in many examples to determine a recommended fertilizer application time and rate for a cereal crop based in part on a tiller density predicted using the correlation model 134. The recommended fertilizer application data 136 and the correlation models 134 can also be used by the computing device 102 in some examples to create the fertilizer application models 138 as described further herein.

The fertilizer application models 138 can include and be indicative of different fertilizer application times and rates recommended for various cereal crops based on ground-truth tiller densities and predicted tiller densities in many cases. The fertilizer application models 138 can each be embodied as a table such as a lookup table in some examples. Each of the fertilizer application models 138 in many cases can include and be indicative of different fertilizer application times and rates recommended for a certain cereal crop based on ground-truth tiller densities and predicted tiller densities determined for the crop. Each of the fertilizer application models 138 can be created by the computing device 102 using the correlation models 134 and the recommended fertilizer application data 136 in many examples. For instance, for a particular cereal crop, the computing device 102 can be configured to implement a corresponding correlation model 134 to predict (e.g., calculate) different tiller densities using aerial-based vegetation indices for the crop that can be obtained from the aerial image data 132. The computing device 102 can be further configured in this example to then determine different fertilizer application times and rates for the different predicted tiller densities using recommended fertilizer application times and rates for the crop that can be obtained from the recommended fertilizer application data 136.

Among other operations, the computing device 102 can be configured to determine a fertilizer application time and rate for a cereal crop using only an aerial-based vegetation index corresponding to the cereal crop in many cases. To determine a fertilizer application time and rate for a cereal crop from an aerial-based vegetation index corresponding to the cereal crop, the computing device 102 can use the correlation engine 120, the model generator 122, the ML-AI models 124, the fertilizer application module 126, the communications stack 128, the tiller density data 130, the aerial image data 132, the correlation models 134, the recommended fertilizer application data 136, and the fertilizer application models 138, among other components, as described in examples herein. Each of the correlation engine 120, the model generator 122, the ML-AI models 124, and the fertilizer application module 126 can be embodied as one or more software applications or services executing on the computing device 102.

The correlation engine 120 can be executed by the processor 112 as described in examples herein to derive a function or equation that defines a relationship between different aerial-based vegetation indices and tiller densities of a certain cereal crop. In this way, the correlation engine 120 can create a multitude of correlation models 134 that each define a relationship between different aerial-based vegetation indices and tiller densities of a certain cereal crop in many examples.

To derive a function or equation that defines a relationship between aerial-based vegetation indices and tiller densities of a cereal crop, the correlation engine 120 can be configured to extract aerial-based vegetation indices for the crop from aerial-based imagery of the crop included in the aerial image data 132. For instance, the correlation engine 120 can extract aerial NDVI and aerial NDRE of a cereal crop from aerial-based images captured using at least one of the UAV 104, the airplane 105, or the satellite 106 and the multispectral imaging camera 154. To extract NDVI and NDRE vegetation indices for a cereal crop from aerial-based images of the crop, the correlation engine 120 can use Equations (1) and (2) defined below:

$$NDVI = ( N I R - R ) / ( NIR + R ) \qquad ( 1 )$$

$$NDRE = ( NIR - RE ) / ( NIR + RE ) \qquad ( 2 )$$

where NIR, R, and RE denote spectral reflectance measurements obtained from near-infrared, red, and red edge (or “edge of red”) regions, respectively. The correlation engine 120 can extract both the NDVI and NDRE indices from each individual plot captured in the aerial-based imagery to obtain an average of NDVI and NDRE for the entire plot. The NDVI and NDRE values extracted from aerial-based imagery using Equations (1) and (2), respectively, are also referred to herein as aerial or aerial-based NDVI and NDRE and as aerial or aerial-based vegetation indices.

To derive a function that defines a relationship between aerial-based vegetation indices and tiller densities of a cereal crop, the correlation engine 120 can be further configured in one example to use aerial NDVI, aerial NDRE, and ground-truth tiller density data 130 corresponding to the crop to determine a correlation coefficient indicative of magnitude and direction of a linear correlation between such aerial-based vegetation indices and ground-truth tiller densities. The correlation engine 120 can also be configured in many examples to use aerial NDVI, aerial NDRE, and ground-truth tiller density data 130 corresponding to a cereal crop to perform a linear regression method to fit a linear correlation between such aerial-based vegetation indices and ground-truth tiller densities. The correlation engine 120 can then define a correlation function or equation indicative of such a linear relationship between the aerial-based vegetation indices and tiller densities of the crop based at least in part on performing the linear regression method in many cases.

Based on performing linear regression (e.g., via a linear regression algorithm and method) using respective aerial image data 132 and tiller density data 130 corresponding to winter wheat in some examples, the correlation engine 120 can define Equations (3) and (4) below:

$$Tiller count = 0.00071 NDVIa + 0 \text{.2623} \qquad ( 3 )$$

$$Tiller count = 0.00064 NDREa + 0.0209 \qquad ( 4 )$$

where NDVIa is aerial NDVI extracted from images captured using the UAV 104 and the multispectral imaging camera 154, and NDREa is aerial NDRE extracted from the same images as the aerial NDVI. Aerial NDVI and NDRE were both significantly correlated (p<0.001) with tiller density in these examples, with 75% (R²=0.75) and 71% (R²=0.71), respectively. Each of Equations (3) and (4) can be an embodiment of one of the correlation models 134 in many cases. The tiller count or density values calculated using Equations (3) and (4) are also referred to herein as predicted tiller counts or densities.

The model generator 122 can be executed by the processor 112 to create a fertilizer application model for a certain cereal crop based at least in part on recommended fertilizer application data for the crop and a relationship between different aerial-based vegetation indices and tiller densities of the crop. The model generator 122 can be configured to implement at least one of Equations (3) or (4) multiple times using different aerial-based NDVI and NDRE to predict different tiller densities for a certain cereal crop. Based on knowing the crop's predicted tiller densities, the model generator 122 can be further configured to use the crop's recommended fertilizer application data 136 to look up recommended fertilizer application times and rates for GS 25 application that correspond to or match the crops predicted tiller densities. In this way, the model generator 122 can create a multitude of fertilizer application models 138 that each include recommended fertilizer application times and rates correlated with and corresponding to different ground-truth tiller densities and predicted tiller densities for a certain cereal crop.

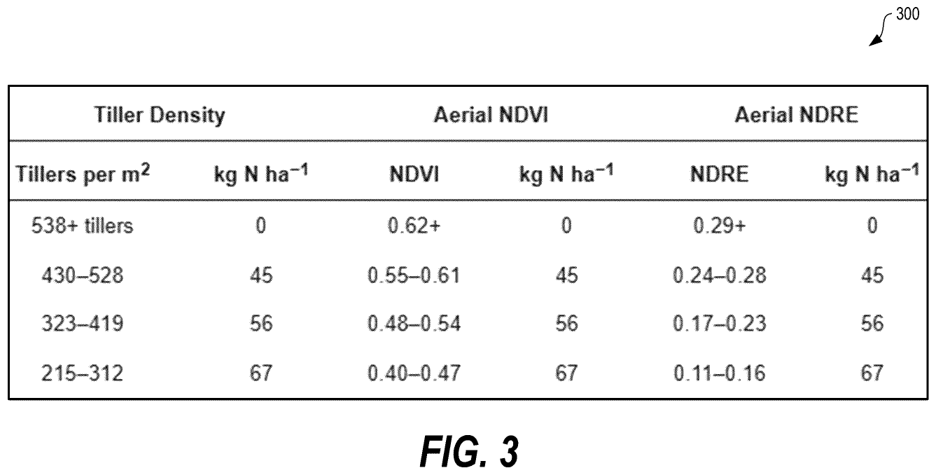

To create a fertilizer application model, the model generator 122 can be configured to create a table in some examples such as a lookup table that includes recommended fertilizer application times and rates corresponding to different ground-truth tiller densities and predicted tiller densities for a certain cereal crop. The model generator 122 can be configured to create the fertilizer application models 138 using the correlation models 134 and the recommended fertilizer application data 136 corresponding to respective cereal crops in many cases. Based on using respective correlation models 134 and recommended fertilizer application data 136 corresponding to winter wheat in some examples, the model generator 122 can create fertilizer application model 300 shown in FIG. 3.

FIG. 3 illustrates an example fertilizer application model 300 according to various aspects and embodiments of the present disclosure. The fertilizer application model 300 is an example of the fertilizer application models 138 that can be created by the model generator 122 using Equations (3) and (4) and recommended fertilizer application times and rates for winter wheat included in the recommended fertilizer application data 136.

As shown in FIG. 3, implementation of Equations (3) and (4) by the model generator 122 in this example yields an aerial NDVI of 0.62 and an aerial NDRE of 0.29, which both correspond to a tiller density of 538 tillers/m², which corresponds to a recommended fertilizer application of 0 kg N ha⁻¹. Additional implementations of Equations (3) and (4) in this example yield an aerial NDVI range of 0.55 to 0.61 and an aerial NDRE range of 0.24 to 0.28, which both correspond to a tiller density range of 430 to 528 tillers/m², which corresponds to a recommended fertilizer application of 45 kg N ha⁻¹. Further implementations of Equations (3) and (4) in this example yield an aerial NDVI range of 0.48 to 0.54 and an aerial NDRE range of 0.17 to 0.23, which both correspond to a tiller density range of 323 to 419 tillers/m², which corresponds to a recommended fertilizer application of 56 kg N ha⁻¹. Still further implementations of Equations (3) and (4) in this example yield an aerial NDVI range of 0.40 to 0.47 and an aerial NDRE range of 0.11 to 0.16, which both correspond to a tiller density range of 215 to 312 tillers/m², which corresponds to a recommended fertilizer application of 67 kg N ha⁻¹.

The recommended fertilizer application rates included in the fertilizer application model 300 are suggested for GS 25 application in this example. The GS 30 recommended fertilizer application rates can be determined from the fertilizer application model 300 based on a summed or total recommended fertilizer application rate for both GS 25 and GS 30 applications (e.g., GS_{total application}=GS 25_{application}+GS 30_{application}). Other fertilizer application models 138 created by the model generator 122 can include recommended fertilizer application rates for GS 30 application, and still other fertilizer application models 138 can include recommended fertilizer application rates for GS 25 and GS 30 application.

Referring again among FIGS. 1 and 2, the ML-AI models 124 can be executed by the processor 112 to perform at least one of a correlation coefficient method or a linear regression method in some examples. The ML-AI models 124 can include various machine learning and artificial intelligence models such as one or more neural networks, deep neural networks, convolutional neural networks (CNN), pattern recognition models, linear regression models, other models, or any combination thereof. The ML-AI models 124 can be implemented by the correlation engine 120 in some examples to determine a correlation coefficient indicative of magnitude and direction of a linear correlation between ground-truth tiller densities included in the tiller density data 130 and aerial-based vegetation indices included in or determined from the aerial image data 132 for a certain cereal crop. The ML-AI models 124 can include a linear regression model in many cases. The linear regression model can be implemented by the correlation engine 120 in many examples using ground-truth tiller densities included in the tiller density data 130 and aerial-based vegetation indices included in or determined from the aerial image data 132 for a certain cereal crop. The linear regression model can be implemented by the correlation engine 120 to fit a linear correlation between the crop's aerial-based vegetation indices and tiller densities to derive a correlation model 134 for the crop.

The fertilizer application module 126 can be executed by the processor 112 to determine at least one of a recommended fertilizer application time or rate for a certain cereal crop based on the crop's aerial-based vegetation index. The fertilizer application module 126 can be configured in many cases to determine such a recommended fertilizer application time or rate using a fertilizer application model 138 created for the crop by the model generator 122. For instance, based on knowing at least one of ground-truth tiller density, predicted tiller density, or an aerial-based vegetation index (e.g., aerial-based NDVI or NDRE) for a certain cereal crop, the fertilizer application module 126 can use the crop's fertilizer application model 138 to look up at least one of a recommended fertilizer application time or rate corresponding to the crop's ground-truth tiller density, predicted tiller density, or aerial-based vegetation index. Based on knowing at least one of tiller density, aerial-based NDVI, or aerial-based NDRE for winter wheat in one example, the fertilizer application module 126 can use the fertilizer application model 300 to look up at least one of a recommended fertilizer application time (e.g., GS 25, GS 30) or rate (e.g., kg N ha⁻¹) corresponding to the crop's tiller density or aerial-based vegetation index.

The communications stack 128 can include software and hardware layers to implement data communications such as, for instance, Bluetooth®, Bluetooth® Low Energy (BLE), WiFi®, cellular data communications interfaces, or a combination thereof. Thus, the communications stack 128 can be relied upon by the computing device 102 to establish cellular, Bluetooth®, WiFi®, and other communications channels with the networks 110 and with at least one of the UAV 104, the airplane 105, the satellite 106, the remote computing devices 107, or the data sources 108.

The communications stack 128 can include the software and hardware to implement Bluetooth®, BLE, and related networking interfaces, which provide for a variety of different network configurations and flexible networking protocols for short-range, low-power wireless communications. The communications stack 128 can also include the software and hardware to implement WiFi® communication, and cellular communication, which also offers a variety of different network configurations and flexible networking protocols for mid-range, long-range, wireless, and cellular communications. The communications stack 128 can also incorporate the software and hardware to implement other communications interfaces, such as X10®, ZigBee®, Z-Wave®, and others.

The communications stack 128 can be configured to communicate various data or information amongst the computing device 102, the UAV 104, the airplane 105, the satellite 106, the remote computing devices 107, and the data sources 108. Examples of such data or information can include, but is not limited to, at least one of data indicative of the tiller density data 130, the aerial image data 132, the correlation models 134, the recommended fertilizer application data 136, the fertilizer application models 138, other data, or any combination thereof.

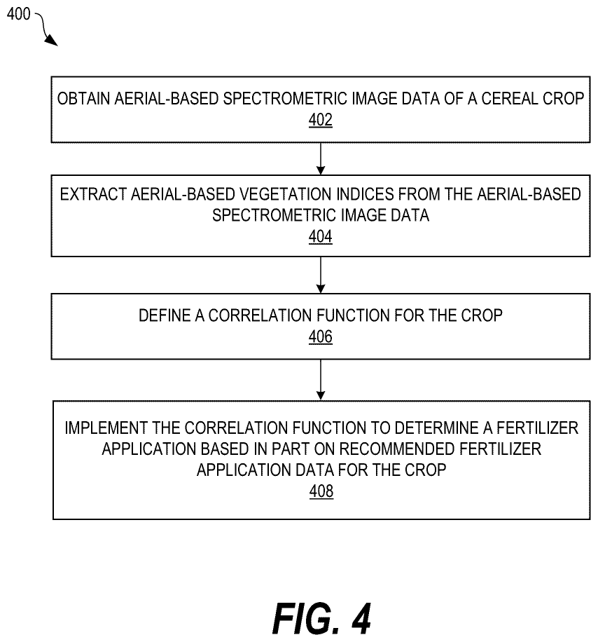

FIG. 4 illustrates a flow diagram of an example computer-implemented method 400 according to various aspects and embodiments of the present disclosure. The computer-implemented method 400 (or “method 400”) can be implemented to determine recommended fertilizer application times and rates for various cereal crops based on aerial-based vegetation indices and tiller densities as described in examples herein. The method 400 can be implemented by the computing device 102 in the context of the environment 100 illustrated in FIGS. 1 and 2 using the correlation engine 120, the model generator 122, the ML-AI models 124, the fertilizer application module 126, the communications stack 128, the tiller density data 130, the aerial image data 132, the correlation models 134, the recommended fertilizer application data 136, and the fertilizer application models 138 as described in various examples herein.

At 402, the method 400 can include obtaining aerial-based spectrometric image data indicative of a cereal crop and captured using at least one of an unmanned aerial vehicle or a satellite. For example, the computing device 102 can obtain the aerial image data 132 for a cereal crop such as winter wheat that has been captured by the multispectral imaging camera 154 using the UAV 104.

At 404, the method 400 can further include extracting aerial-based vegetation indices for the cereal crop from the aerial-based spectrometric image data. For example, as described above with reference to FIGS. 1 and 2, the computing device 102 can implement the correlation engine 120 to extract aerial-based NDVI and NDRE from aerial image data 132 for winter wheat using Equations (1) and (2).

At 406, the method 400 can further include defining a correlation function indicative of a relationship between the crop's aerial-based vegetation indices and ground-truth tiller densities determined for the crop. For example, as described above with reference to FIGS. 1 and 2, the computing device 102 can implement the correlation engine 120 to derive Equations (3) and (4) by performing a linear regression method using tiller density data 130 for winter wheat and aerial-based NDVI and NDRE extracted from aerial image data 132 for winter wheat.

At 408, the method 400 can further include implementing the correlation function to determine at least one of a recommended fertilizer application time or rate based at least in part on recommended fertilizer application data for the crop. For example, as described above with reference to FIGS. 1 and 2, the computing device 102 can implement the model generator 122 to calculate different predicted tiller densities for a certain cereal crop using Equations (3) and (4). Based on knowing the crop's predicted tiller densities, the computing device 102 can then implement at least one of the model generator 122 or the fertilizer application module 126 in many examples to look up different recommended fertilizer application rates for GS 25 application that correspond to or match the crop's predicted tiller densities (e.g., the crop's tiller densities predicted using Equations (3) and (4) and aerial-based vegetation indices determined for GS 25 application and time period).

In some cases, the model generator 122 can use recommended fertilizer application data 136 for a certain cereal crop to look up different recommended fertilizer application rates for GS 25 application that correspond to or match the crop's predicted tiller densities. In other examples, the fertilizer application module 126 can use a fertilizer application model 138 created for the crop to look up different recommended fertilizer application rates for GS 25 application that correspond to or match the crop's predicted tiller densities. For instance, based on knowing at least one of ground-truth tiller density, predicted tiller density, aerial-based NDVI, or aerial-based NDRE for winter wheat, the fertilizer application module 126 can use the fertilizer application model 300 to look up different recommended fertilizer application rates (e.g., kg N ha⁻¹) for GS 25 that correspond to the wheat's tiller density or aerial-based vegetation index.

In developing many embodiments herein, four site-years were selected from 2018 to 2020 in one example to determine the relationship between NDVI/NDRE and tiller density. In the 2018-2019 growing season, research was conducted in this example at a first location (Location 1), a second location (Location 2), and a third location (Location 3), while in the 2019-2020 growing season, research was conducted at Location 1 only. Planting and harvest dates and soil type information for each location in this example were recorded. GS 25 N was also applied in small plot trials in this example from 2019 to 2021 using a fertilizer application model developed as described herein. These trials were located at Location 1 and Location 3 during the 2020-2021 growing season.

At each location in this example, a cultivar known as “Hilliard” was planted at a seeding rate of 144 seeds per meter (m⁻¹) with a Hege plot drill in seven row plots that measured 2.74 m long×1.52 m wide. Plots were planted in conventionally tilled fields at Location 1 and Location 2 and no-till at Location 3. The plots from 2018 to 2020 were used for linear regression model development and they were arranged in a randomized complete block design (RCBD) with four replications, and with N rate and application timing being the main effects. The rates and timing were selected to achieve a diverse combination of rates split among GS 25 and GS 30, and totaling 134.5 kg N ha⁻¹, which is the optimum N recommended for high yield production of winter wheat in Locations 1, 2, and 3. Nitrogen applications were made using 12-0-0-1.5 at GS 25 and 24-0-0-3 at GS 30 and were applied with a backpack sprayer. In this way, seven combinations were designed. In addition, five more N rates and timing combinations were created, with the purpose of generating differing tiller densities. Planting and harvest information for each location were recorded. Based on these data sets, two linear regression models or correlation models (e.g., the correlation models 134) were developed for NDVI and NDRE to predict tiller density, and these models were used to determine N rates at GS 25 in small plot trials at Location 1 and Location 3 during the 2020-2021 growing season.

In another example during the 2020-2021 growing season, plots received N at GS 25 based on either direct count of tiller density or aerial NDVI and NDRE imaging using the aforementioned regression models (e.g., the correlation models 134) developed as described herein. GS 30 N application was based on the amount of N applied at GS 25 in order to achieve a total of 134.5 kg N ha⁻¹. These application methods were arranged in an RCBD with four replications. Planting and harvest information, N rates, timing, and methods for each location were recorded.

After regression models (e.g., the correlation models 134) between tiller density and vegetation indices were established and tested in small plots in 2020-2021, these models were validated in another example in large scale settings in growers' fields. Six site-year combinations were established from 2021 to 2023 in this example. In the 2021-2022 growing season, sites were established in growers' fields at a fourth location (Location 4), a fifth location (Location 5), and a sixth location (Location 6). In the 2022-2023 growing season, sites were established in growers' fields at Location 4, a seventh location (Location 7), and an eighth location (Location 8). Information on location, planting and harvest dates, soil type and tillage, and plot size were recorded. The plot size was dependent on the growers' spray equipment. Nitrogen rates were based on the direct count of tiller density and NDVI- and NDRE-based regression models (e.g., the correlation models 134) developed in small plots as described in examples herein. Strips were arranged in an RCBD with three replications for each N application at GS 25. For instance, aerial NDVI- and NDRE-based models, and direct tiller count, were implemented at all locations with the exception of Location 8 in 2023, where only aerial NDVI and tiller density were used due to land constraints. GS 30 N application was based on the amount of N applied at GS 25 in order to achieve a total of 134.5 kg N ha⁻¹. The recommended N rate by each model at GS 25 was compared with the rate based on tiller density count. Each strip was combined individually at harvest to determine grain yield differences based on the N application method.

Tiller density was collected in multiple places (e.g., three or four places) in another example, in both the small plots and large on-farm trials, throughout the growing season. Tiller density was directly counted and the number of tillers per square meter was calculated. Aerial images were collected from all research plots on the same day tiller density was collected in order to extract aerial NDVI and aerial NDRE. Dates that aerial images and tiller density were collected was also recorded. A multispectral camera or sensor (e.g., MicaSense RedEdge sensor) affixed to an UAV (e.g., DJI Matrice 100) was used in this example to collect aerial images. Images were collected at an altitude of 50 m with a 75% overlap flight plan using a flight plan application (e.g., Atlas Flight) in this case. The UAV (e.g., the UAV 104 including the computing device 102 and the multispectral imaging camera 154) used its built-in GPS to navigate, acquire, and store the images. After each flight, images were merged (e.g., via the computing device 102 and the multispectral imaging camera 154) into orthomosaics in a photogrammetry and drone mapping application (e.g., Pix4D software). Orthomosaic images were calibrated using the calibration panel of the multispectral camera (e.g., the multispectral imaging camera 154). Using the NDVI and NDRE formulas (e.g., Equations (1) and (2)) in the photogrammetry and drone mapping application index calculator where:

$$NDVI = ( N I R - R ) / ( NIR + R ) \qquad ( 1 )$$

$$NDRE = ( NIR - RE ) / ( NIR + RE ) \qquad ( 2 )$$

both indices were extracted from each individual plot in this example to obtain an average of NDVI and NDRE for the entire plot. Grain yield was collected with a plot combine in the small research plots and with the growers combine for on-farm trials. In Equations (1) and (2), NIR, R, and RE denote spectral reflectance measurements obtained from near-infrared, red, and red edge (or “edge of red”) regions, respectively.

Correlation coefficient determinations such as Pearson correlation coefficient determinations between tiller density and the two aerial indices were performed (e.g., via the correlation engine 120) in a statistical application (e.g., SAS software) in this example. Linear regression was used (e.g., via the correlation engine 120) in this example to fit the relationship between tiller density counts and the NDVI and NDRE. Proc GLM procedure was used in this example to determine the effect of N rate decision tool on N applied and yield using a statistical application (e.g., SAS 9.4 software).

Results from the small plot trials across four site-years showed that tiller density was significantly correlated (p<0.001) with aerial NDVI with 75% (R²=0.75). This relationship is defined by the above-described Equation (3):

$$Tiller count = 0.00071 NDVIa + 0 \text{.2623} \qquad ( 3 )$$

where NDVIa is aerial NDVI extracted from images taken at 50 m altitude with 75% forward and lateral overlay. Aerial NDRE was also significantly correlated (p<0.001) with tiller density with an R²=0.71. The model describing this relationship is defined as the aforementioned Equation (4):

$$Tiller count = 0.00064 NDREa + 0.0209 \qquad ( 4 )$$

where NDREa is aerial NDRE extracted from the same images as the aerial NDVI.

Previous research (e.g., the recommended fertilizer application data 136) has shown that a winter wheat crop with 538 tillers/m² or more at GS 25 does not need any N application at this time. Using this base line and the linear regression Equations (3) and (4) derived from the small plot trials, aerial-based NDVI and NDRE values at which N should be applied and the amount that should be applied were determined in this example. For instance, the Equations (3) and (4) show that 538 tillers/m² correspond to an aerial NDVI of 0.62 and an aerial NDRE of 0.29 (e.g., FIG. 3). Therefore, at GS 25, if the crop has an aerial NDVI of 0.62 or greater, then N should not be applied. If the aerial NDVI is less than 0.62, then N should be applied. The fertilizer application model 300 illustrated in FIG. 3 shows which rates should be applied at which aerial NDVI and NDRE values and how this corresponds to tiller density for winter wheat in some examples. These data show that aerial NDVI and NDRE are excellent proxies for tiller density as they can be used to accurately determine tiller density in winter wheat.

Using the example values in the fertilizer application model 300, GS 25 N was applied using the NDVI and NDRE and compared to tiller density at Location 1 and Location 3 in 2021 in another example. At Location 1, NDVI and NDRE recommended 56 kg N ha⁻¹ in this example, while tiller density recommended 0 kg N ha⁻¹. At Location 3, tiller density, NDVI, and NDRE all recommended 36 kg N ha⁻¹ at GS 25 in this case. Analysis of variance showed that there was no difference in grain yield among the three N rate decision methods at either location. These data further demonstrate how aerial NDVI and NDRE are excellent proxies for tiller density as they can be used to accurately determine at least one of an N application rate or time (e.g., G25, G30) for winter wheat.

In 2021-2022 and 2022-2023 in another example, the N rates derived from aerial NDVI and NDRE in the fertilizer application model 300 were used for GS 25 applications in the on-farm large plots. Analysis of variance of N applied at GS 25 in this example showed no significant location×rate decision method interaction. At Location 5 and Location 6 in 2022, and at Location 8 in 2023, there was no significant difference between the amount of N recommended by NDVI, NDRE, or tiller density. There was a significant difference in the amount of N recommended at Location 4 in 2022 as NDVI and NDRE recommended 67.3 kg N ha⁻¹, and tiller density only 22.4 kg N ha⁻¹. At Location 4 and Location 7 in 2023, tiller density recommended significantly more N to be applied at GS 25. The tiller density method recommended 44.8 kg N ha⁻¹ to be applied at GS 25 at Location 7 in 2023 and 26.9 kg N ha⁻¹ at Location 4 in 2023, while NDVI and NDRE recommended that no N was needed at either location. The difference in recommended N rate between methods in this example can be attributed to the location and field variability, which was better accounted for using aerial images than physically counting tillers (e.g., NDVI and NDRE averaged the entire strip and tiller counting was at random locations within the strip).

There were no significant differences among the N application methods across locations for grain yield and there was no location×application method interaction in this on-farm trials example. Grain yield was 6.12 t ha⁻¹ when N was applied based on aerial NDRE, 6.05 t ha⁻¹ when N was applied based on aerial NDVI, and 5.92 when N was applied based on counted tiller density.

Referring now to FIGS. 1 and 2, an executable program can be stored in any portion or component of the memory 114. The memory 114 can be embodied as, for example, a random access memory (RAM), read-only memory (ROM), magnetic or other hard disk drive, solid-state, semiconductor, universal serial bus (USB) flash drive, memory card, optical disc (e.g., compact disc (CD) or digital versatile disc (DVD)), floppy disk, magnetic tape, or other types of memory devices.

The memory 114 can include both volatile and nonvolatile memory and data storage components. Volatile components are those that do not retain data values upon loss of power. Nonvolatile components are those that retain data upon a loss of power. Thus, the memory 114 can include, for example, a RAM, ROM, magnetic or other hard disk drive, solid-state, semiconductor, or similar drive, USB flash drive, memory card accessed via a memory card reader, floppy disk accessed via an associated floppy disk drive, optical disc accessed via an optical disc drive, magnetic tape accessed via an appropriate tape drive, and/or other memory component, or any combination thereof. In addition, the RAM can include, for example, a static random-access memory (SRAM), dynamic random-access memory (DRAM), or magnetic random-access memory (MRAM), and/or other similar memory device. The ROM can include, for example, a programmable read-only memory (PROM), erasable programmable read-only memory (EPROM), electrically erasable programmable read-only memory (EEPROM), or other similar memory devices.

As discussed above, the correlation engine 120, the model generator 122, the ML-AI models 124, the fertilizer application module 126, and the communications stack 128 can each be embodied, at least in part, by software or executable-code components for execution by general purpose hardware. Alternatively, the same can be embodied in dedicated hardware or a combination of software, general, specific, and/or dedicated purpose hardware. If embodied in such hardware, each can be implemented as a circuit or state machine, for example, that employs any one of or a combination of a number of technologies. These technologies can include, but are not limited to, discrete logic circuits having logic gates for implementing various logic functions upon an application of one or more data signals, application specific integrated circuits (ASICs) having appropriate logic gates, field-programmable gate arrays (FPGAs), or other components.

Referring now to FIG. 4, the flowchart or process diagram shown in FIG. 4 is representative of certain processes, functionality, and operations of the embodiments discussed herein. Each block can represent one or a combination of steps or executions in a process. Alternatively, or additionally, each block can represent a module, segment, or portion of code that includes program instructions to implement the specified logical function(s). The program instructions can be embodied in the form of source code that includes human-readable statements written in a programming language or machine code that includes numerical instructions recognizable by a suitable execution system such as the processor 112. The machine code can be converted from the source code. Further, each block can represent, or be connected with, a circuit or a number of interconnected circuits to implement a certain logical function or process step.

Although the flowchart or process diagram shown in each of FIG. 4 illustrates a specific order, it is understood that the order can differ from that which is depicted. For example, an order of execution of two or more blocks can be scrambled relative to the order shown. Also, two or more blocks shown in succession can be executed concurrently or with partial concurrence. Further, in some embodiments, one or more of the blocks can be skipped or omitted. In addition, any number of counters, state variables, warning semaphores, or messages might be added to the logical flow described herein, for purposes of enhanced utility, accounting, performance measurement, or providing troubleshooting aids. Such variations, as understood for implementing the process consistent with the concepts described herein, are within the scope of the embodiments.

Also, any logic or application described herein, including the correlation engine 120, the model generator 122, the ML-AI models 124, the fertilizer application module 126, and the communications stack 128 can be embodied, at least in part, by software or executable-code components, can be embodied or stored in any tangible or non-transitory computer-readable medium or device for execution by an instruction execution system such as a general-purpose processor. In this sense, the logic can be embodied as, for example, software or executable-code components that can be fetched from the computer-readable medium and executed by the instruction execution system. Thus, the instruction execution system can be directed by execution of the instructions to perform certain processes such as those illustrated in FIG. 4. In the context of the present disclosure, a non-transitory computer-readable medium can be any tangible medium that can contain, store, or maintain any logic, application, software, or executable-code component described herein for use by or in connection with an instruction execution system.

The computer-readable medium can include any physical media such as, for example, magnetic, optical, or semiconductor media. More specific examples of suitable computer-readable media include, but are not limited to, magnetic tapes, magnetic floppy diskettes, magnetic hard drives, memory cards, solid-state drives, USB flash drives, or optical discs. Also, the computer-readable medium can include a RAM including, for example, an SRAM, DRAM, or MRAM. In addition, the computer-readable medium can include a ROM, a PROM, an EPROM, an EEPROM, or other similar memory device.

Disjunctive language, such as the phrase “at least one of X, Y, or Z,” unless specifically stated otherwise, is to be understood with the context as used in general to present that an item, term, or the like, can be either X, Y, or Z, or any combination thereof (e.g., X, Y, and/or Z). Thus, such disjunctive language is not generally intended to, and should not, imply that certain embodiments require at least one of X, at least one of Y, or at least one of Z to be each present. As referenced herein in the context of quantity, the terms “a” or “an” are intended to mean “at least one” and are not intended to imply “one and only one.”

As referred to herein, the terms “includes” and “including” are intended to be inclusive in a manner similar to the term “comprising.” As referenced herein, the terms “or” and “and/or” are generally intended to be inclusive, that is (i.e.), “A or B” or “A and/or B” are each intended to mean “A or B or both.” As referred to herein, the terms “first,” “second,” “third,” and so on, can be used interchangeably to distinguish one component or entity from another and are not intended to signify location, functionality, or importance of the individual components or entities. As referenced herein, the terms “couple,” “couples,” “coupled,” and/or “coupling” refer to chemical coupling (e.g., chemical bonding), communicative coupling, electrical and/or electromagnetic coupling (e.g., capacitive coupling, inductive coupling, direct and/or connected coupling), mechanical coupling, operative coupling, optical coupling, and/or physical coupling.

It should be emphasized that the above-described embodiments of the present disclosure are merely possible examples of implementations set forth for a clear understanding of the principles of the disclosure. Many variations and modifications can be made to the above-described embodiment(s) without departing substantially from the spirit and principles of the disclosure. All such modifications and variations are intended to be included herein within the scope of this disclosure and protected by the following claims.

Therefore, at least the following is claimed:

1. A computing device, comprising:
a memory device to store computer-readable instructions thereon; and
at least one processing device configured through execution of the computer-readable instructions to:
determine a relationship between an aerial vegetation index for a cereal crop and tiller density of the cereal crop; and
create a fertilizer application model for the cereal crop based at least in part on recommended fertilizer application data for the cereal crop and the relationship between the aerial vegetation index and the tiller density of the cereal crop, the recommended fertilizer application data being correlated with the tiller density of the cereal crop.

2. The computing device of claim 1, wherein the at least one processing device is further configured to:
determine at least one of a fertilizer application time or a fertilizer application rate for the cereal crop using the fertilizer application model.

3. The computing device of claim 1, wherein to determine the relationship between the aerial vegetation index and the tiller density, the at least one processing device is further configured to:
obtain aerial-based spectrometric image data indicative of the cereal crop and captured using at least one of an unmanned aerial vehicle or a satellite; and
calculate the aerial vegetation index based at least in part on the aerial-based spectrometric image data.

4. The computing device of claim 1, wherein to determine the relationship between the aerial vegetation index and the tiller density, the at least one processing device is further configured to:
determine a correlation coefficient of a linear correlation between the aerial vegetation index and ground-truth tiller density of the cereal crop, the correlation coefficient being indicative of magnitude and direction of the linear correlation.

5. The computing device of claim 1, wherein to determine the relationship between the aerial vegetation index and the tiller density, the at least one processing device is further configured to:
perform a linear regression method to fit a linear correlation between the aerial vegetation index and ground-truth tiller density of the cereal crop; and
define a correlation function indicative of the relationship between the aerial vegetation index and at least one of the tiller density or the ground-truth tiller density based at least in part on performing the linear regression method to fit the linear correlation.

6. The computing device of claim 1, wherein to create the fertilizer application model for the cereal crop, the at least one processing device is further configured to:
define a correlation function indicative of the relationship between the aerial vegetation index and the tiller density;
implement the correlation function to calculate different tiller densities corresponding to different aerial vegetation indices; and
determine different fertilizer application times and rates for the different tiller densities based at least in part on the recommended fertilizer application data for the cereal crop.

7. The computing device of claim 1, wherein the aerial vegetation index comprises an aerial-based normalized difference vegetation index or an aerial-based normalized difference red edge index.

8. The computing device of claim 1, wherein the cereal crop comprises at least one of wheat, winter wheat, rice, corn, barley, oats, rye, millet, or sorghum.

9. A computer-implemented method for determining fertilizer application, the method comprising:
determining, by a computing device, a relationship between an aerial vegetation index for a crop and tiller density of the crop; and
creating, by the computing device, a fertilizer application model for the crop based at least in part on recommended fertilizer application data for the crop and the relationship between the aerial vegetation index and the tiller density of the crop, the recommended fertilizer application data being correlated with the tiller density of the crop.

10. The method of claim 9, further comprising:
determining, by the computing device, at least one of a fertilizer application time or rate for the crop using the fertilizer application model.

11. The method of claim 9, wherein determining the relationship between the aerial vegetation index and the tiller density comprises:
obtaining, by the computing device, aerial-based spectrometric image data indicative of the crop and captured using at least one of an unmanned aerial vehicle or a satellite; and
calculating, by the computing device, the aerial vegetation index based at least in part on the aerial-based spectrometric image data.

12. The method of claim 9, wherein determining the relationship between the aerial vegetation index and the tiller density comprises:
determining, by the computing device, a correlation coefficient of a linear correlation between the aerial vegetation index and ground-truth tiller density of the crop, the correlation coefficient being indicative of magnitude and direction of the linear correlation.

13. The method of claim 9, wherein determining the relationship between the aerial vegetation index and the tiller density comprises:
performing, by the computing device, a linear regression method to fit a linear correlation between the aerial vegetation index and ground-truth tiller density of the crop; and
defining, by the computing device, a correlation function indicative of the relationship between the aerial vegetation index and at least one of the tiller density or the ground-truth tiller density based at least in part on performing the linear regression method to fit the linear correlation.

14. The method of claim 9, wherein creating the fertilizer application model for the crop comprises:
defining, by the computing device, a correlation function indicative of the relationship between the aerial vegetation index and the tiller density;
implementing, by the computing device, the correlation function to calculate different tiller densities corresponding to different aerial vegetation indices; and
determining, by the computing device, different fertilizer application times and rates for the different tiller densities based at least in part on the recommended fertilizer application data for the crop.

15. An unmanned aerial vehicle, comprising:
a multispectral camera configured to capture aerial-based spectrometric image data indicative of a crop; and
a computing device configured to:
calculate an aerial vegetation index for the crop based at least in part on the aerial-based spectrometric image data;
determine a relationship between the aerial vegetation index and tiller density of the crop; and
determine at least one of a fertilizer application time or a fertilizer application rate for the crop based at least in part on the relationship between the aerial vegetation index and the tiller density.

16. The unmanned aerial vehicle of claim 15, wherein the computing device is further configured to:
determine at least one of the fertilizer application time or the fertilizer application rate for the crop based at least in part on recommended fertilizer application data for the crop and the relationship between the aerial vegetation index and the tiller density of the crop, the recommended fertilizer application data being correlated with the tiller density of the crop.

17. The unmanned aerial vehicle of claim 15, wherein the computing device is further configured to:
create a fertilizer application model for the crop based at least in part on recommended fertilizer application data for the crop and the relationship between the aerial vegetation index and the tiller density of the crop, the recommended fertilizer application data being correlated with the tiller density of the crop.

18. The unmanned aerial vehicle of claim 15, wherein to determine the relationship between the aerial vegetation index and the tiller density, the computing device is further configured to:
determine a correlation coefficient of a linear correlation between the aerial vegetation index and ground-truth tiller density of the crop, the correlation coefficient being indicative of magnitude and direction of the linear correlation.

19. The unmanned aerial vehicle of claim 15, wherein to determine the relationship between the aerial vegetation index and the tiller density, the computing device is further configured to:
perform a linear regression method to fit a linear correlation between the aerial vegetation index and ground-truth tiller density of the crop; and
define a correlation function indicative of the relationship between the aerial vegetation index and at least one of the tiller density or the ground-truth tiller density based at least in part on performing the linear regression method to fit the linear correlation.

20. The unmanned aerial vehicle of claim 17, wherein to create the fertilizer application model for the crop, the computing device is further configured to:
define a correlation function indicative of the relationship between the aerial vegetation index and the tiller density;
implement the correlation function to calculate different tiller densities corresponding to different aerial vegetation indices; and
determine different fertilizer application times and rates for the different tiller densities based at least in part on the recommended fertilizer application data for the crop.
